(19) United States
(12) Patent Application Publication
(10) Pub. No.: US 2026/0191062 A1
(43) Pub. Date: Jul. 2, 2026

(54) SEMICONDUCTOR PACKAGE

(71) Applicant: MEDIATEK INC., Hsinchu City (TW)

(72) Inventor: Hsing-Chih LIU, Hsinchu City (TW)

(21) Appl. No.: 19/428,905

(22) Filed: Dec. 22, 2025

Related U.S. Application Data
(60) Provisional application No. 63/739,715, filed on Dec. 30, 2024.

(51) Int. Cl. H10W 70/685; H10B 80/00; H10D 80/30; H10W 70/60; H10W 70/63; H10W 70/692; H10W 70/695; H10W 74/10; H10W 74/15; H10W 90/00; H10W 90/10

(52) U.S. Cl. CPC H10W 70/685; H10W 70/611; H10W 70/635; H10W 70/692; H10W 70/695; H10W 74/117; H10W 90/10; H10B 80/00; H10D 80/30; H10W 74/15; H10W 90/401; H10W 90/724

(57) ABSTRACT

A semiconductor package is provided. The semiconductor package includes a glass carrier, a redistribution layer (RDL) structure, a first die, a molding compound and a plurality of conductive ball structures. The RDL structure is directly disposed on a first surface of the glass carrier. The first die is mounted on the RDL structure. The molding compound is disposed on the RDL structure and surrounding the first die. The plurality of conductive ball structures is disposed on a second surface of the glass carrier. The second surface is opposite the first surface.

### CROSS REFERENCE TO RELATED APPLICATIONS

This application claims the benefit of U.S. provisional application No. 63/739,715, filed on Dec. 30, 2024, the entirety of which is incorporated by reference herein.

### TECHNICAL FIELD

The present disclosure relates to a semiconductor package, and, in particular, it relates to a semiconductor package including a glass carrier.

### BACKGROUND

The continuous drive for higher computing power and higher data bandwidth to meet the growing demand from applications in data centers, networking, and artificial intelligence has driven the development of advanced packaging solutions for devices with higher levels of performance. However, for high-speed, compact products, achieving high-density routing and maintaining a low-cost package are requirements that are a challenge to meet.

Thus, a novel semiconductor package is needed to fulfill the requirements of high-density routing in a low-cost package.

### BRIEF SUMMARY

An embodiment of the present disclosure provides a semiconductor package. The semiconductor package includes a glass carrier, a redistribution layer (RDL) structure, a first die, a molding compound and a plurality of conductive ball structures. The RDL structure is directly disposed on a first surface of the glass carrier. The first die is mounted on the RDL structure. The molding compound is disposed on the RDL structure and surrounding the first die. The plurality of conductive ball structures is disposed on a second surface of the glass carrier. The second surface is opposite the first surface.

An embodiment of the present disclosure provides a semiconductor package. The semiconductor package includes a glass carrier, an organic redistribution layer (RDL) structure, a first die, a molding compound and a plurality of conductive ball structures. The organic RDL structure is directly disposed on a first surface of the glass carrier. The first die is mounted on the organic RDL structure and opposite the glass carrier. The molding compound is disposed on the organic RDL structure and surrounding the first die. The plurality of conductive ball structures is disposed on a second surface of the glass carrier. The second surface is opposite the first surface.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor package in accordance with some embodiments of the disclosure; and

FIG. 2 is a schematic cross-sectional view of a semiconductor package in accordance with some embodiments of the disclosure.

### DETAILED DESCRIPTION

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

The trend of applying high-density (fine trace width/space) RDL in packages for high-speed channels is increasing. For high performance computing (HPC) products, special package structures are adopted to meet the demanding performance requirements. Examples include the Chip-on-Wafer-on-Substrate (CoWoS) package, which features high-density routing with fine trace width and spacing in the redistribution layer (RDL). In addition, organic redistribution layer (O-RDL) allowing to be fabricated in a thin thickness can be used. Moreover, the glass substrate technology, which enables larger package sizes, higher speeds, and better overall performance is also adopted.

However, larger package sizes would easily cause stress/damage to the thin organic redistribution layer (O-RDL) during ball level reliability (BLR) or product high/low temperature operation, compared to thicker or more rigid substrates. Thus, a novel structure for a semiconductor package is desirable.

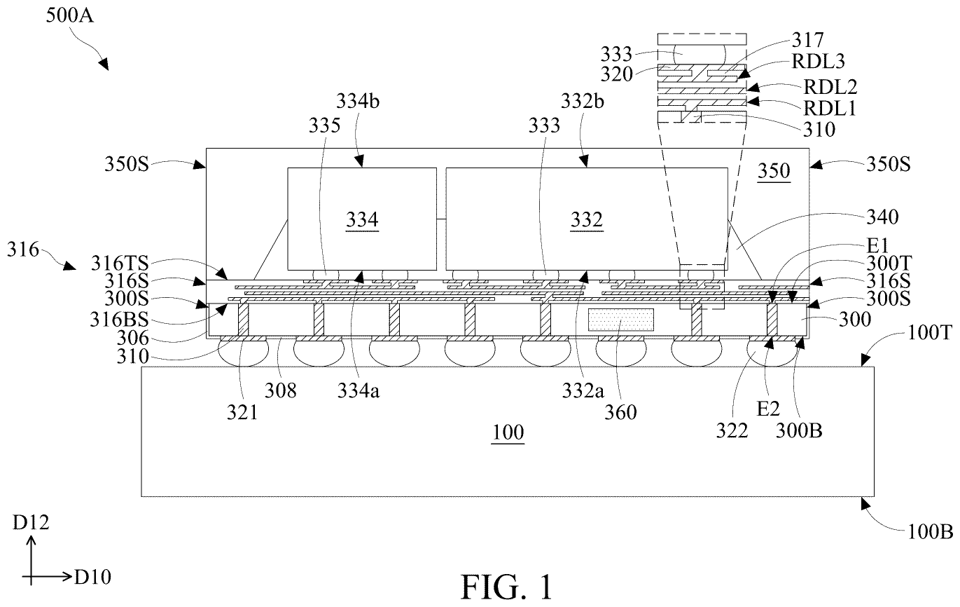

FIG. 1 is a cross-sectional view of a semiconductor package 500A in accordance with some embodiments of the disclosure. In some embodiments, the semiconductor package 500A can be used to form a two-dimensional (2D) package, a 2.5D package, a three-dimensional (3D) semiconductor package, a 3.5D semiconductor package, or another suitable package. The semiconductor package 500A may be mounted on a base 100. In some embodiments, the semiconductor package 500A may not include the base 100; that is, the base 100 is external to the semiconductor package 500A. In FIG. 1 and the following figures, the direction D10 is defined as horizontal directions (also regarded as the extending directions of conductive layers and/or conductive traces of the semiconductor package 500A), and the direction D12 is defined as a vertical direction (also regarded as the extending direction of the through via and/or vias of the semiconductor package 500A).

As shown in FIG. 1, the base 100 can be a single layer or a multilayer structure. In some embodiments, the base 100 is, for example, a printed circuit board (PCB), an interposer, a package substrate, another semiconductor device or a semiconductor package. In some embodiments, the base 100 may be formed of dielectric materials (e.g., polypropylene (PP), epoxy, polyimide, or other applicable resin materials) or semiconductor materials. The base 100 has a top surface 100T and a bottom surface 100B opposite the top surface 100T. The base 100 is provided for the semiconductor package 500A disposed on the top surface 100T. A plurality of conductive traces (not shown), conductive vias and/or conductive pads (not shown) are disposed in the base 100. The conductive traces may be electrically connected to the corresponding conductive vias and conductive pads. The conductive pads and/or the conductive traces are exposed to openings of solder mask layers (not shown) disposed close to the top surface 100T and the bottom surface 100B. In one embodiment, the conductive traces may comprise signal trace segments or ground trace segments, which are used for the input/output (I/O) connections of the semiconductor package 500A. Also, the conductive pads are disposed on the top surface 100T of the base 100, connected to different terminals of the conductive traces. The conductive pads are used for the semiconductor package 500A that is mounted directly on them.

As shown in FIG. 1, the semiconductor package 500A is mounted on the base 100 through a bonding process that uses conductive ball structures 322. The semiconductor package 500A includes a glass carrier 300, a redistribution layer (RDL) structure 316, a first die 332, a second die 334, a molding compound 350 and a plurality of conductive ball structures 322.

In some embodiments, the glass carrier 300 is used as a carrier for a chip-last process of the semiconductor package 500A. The glass carrier 300 has opposite surfaces 300T and 300B and opposite side surfaces 300S connected between the surfaces 300T and 300B.

In some embodiments, the semiconductor package 500A may further include one or more passivation films covering one or more surfaces of the glass carrier 300 not covered by the RDL structure 316. For example, the semiconductor package 500A may further include passivation film 306 covering opposite side surfaces 300S of the glass carrier 300. In addition, the semiconductor package 500A may further include passivation film 308 covering the surface 300B (or a second surface) close to the conductive ball structures 322. In some embodiments, the passivation films 306 and 308 may be formed of polyimide (PI) or other applicable insulating materials. In some embodiments, the outer side wall of the passivation film 306 may be flushed with a corresponding side surface 316S of the RDL structure 316. In some embodiments, the passivation films 306 and 308 may be used to protect the glass carrier 300. In some embodiments, there is no passivation film or other layer on the surface 300T of the glass carrier 300, allowing the RDL structure 316 to directly contact the surface 300T. This direct contact enhances the support for the RDL structure 316, leading to improved structural stability and electrical connection.

The RDL structure 316 is directly disposed on the surface (or a first surface) 300T of the glass carrier 300. The RDL structure 316 is provided for the first die 332 and the second die 334 mounted on it to redistribute and fan-out one or more of die pads of the first die 332 and the second die 334 with a small pitch to the conductive pads on the surface 300B of the glass carrier 300 which are coupled to the corresponding conductive ball structures 322 having a larger pitch.

The RDL structure 316 may have opposite surfaces 316TS and 316BS. The surface 316TS of the RDL structure 316 is provided for the first die 332 and the second die 334 directly to be disposed upon and is also called a die attached surface. The surface 316BS of the RDL structure 316 is provided for the glass carrier 300 directly to be disposed upon and is also called a glass carrier attached surface.

In some embodiments, the RDL structure 316 may include one or more RDL layers (e.g. RDL layers RDL1, RDL2 and RDL3 shown in FIG. 1) alternatively arranged with one or more dielectric layers 317, and conductive pads 320. The RDL layers RDL1, RDL2 and RDL3 are formed on the corresponding dielectric layers 317 and fills one or more openings (not shown) in the corresponding dielectric layers 317. In some embodiments, the RDL layers RDL1, RDL2 and RDL3 includes conductive layers, vias, and conductive pads.

In some embodiments, the RDL structure 316 is an organic RDL structure. The RDL layers RDL1, RDL2 and RDL3 include a conductive material, such as metals including copper, gold, silver, or other applicable metals. The dielectric layers 317 may be formed of organic polymer, including polyimide (PI), polybenzoxazole (PBO), benzocyclobutene (BCB), epoxy, Ajinomoto build-up film (ABF), Bismaleimide-Triazine (BT resin), another suitable organic dielectric material, or a combination thereof, but it is not limited thereto. In some embodiments, the dielectric layers 317 may be formed by a lamination process, a spin coating process, a chemical vapor deposition (CVD) process, or another applicable process. In accordance with some embodiment, the dielectric layers 317 may be patterned through one or more photolithography processes and/or etching processes. It should be noted that the number of RDL layers and the dielectric layers 317 shown in FIG. 1 are only an example and is not a limitation to the present disclosure.

In some embodiments, the glass carrier 300 may completely overlap the RDL structure 316 in the direction D12. As shown in FIG. 1, a side surface 300S of the glass carrier 300 may be flush with a corresponding side surface 316S of the RDL structure 316. Therefore, the side surface 300S of the glass carrier 300 may be exposed from the RDL structure 316. In some embodiments, in a plan view, the size (or the area) of the glass carrier 300 is the same as the size (or the area) of the RDL structure 316. In some embodiments, the side surface 300S of the glass carrier 300 is positioned lower than the corresponding side surface 316S of the RDL 316 structure in the horizontal direction (the direction D10).

The conductive ball structures 322 are disposed on the surface 300B (or the second surface) of the glass carrier 300 and coupled between the RDL structure 316 and the base 100. In some embodiments, the conductive ball structures 322 include copper balls or solder balls.

In some embodiments, the semiconductor package 500A may further include at least one through glass via (TGV) 310 and at least one conductive pad 321. The TGV 310 may be formed filling a through hole (not shown) passing through the glass carrier 300 for signal, power, and ground connections from the RDL structure 316 to the conductive ball structure 322. The through hole may be formed by a drilling process (e.g., mechanical drilling). In other words, the TGV 310 may pass through the glass carrier 300. In addition, the conductive pad 321 is formed on the surface 300B of the glass carrier 300 and directly covers the corresponding TGV 310.

As shown in FIG. 1, opposite ends E1 and E2 of the TGV 310 may be exposed from the surfaces 300T and 300B of the glass carrier 300. The TGV 310 is connected (and coupled) between the RDL structure 316 and one of the conductive ball structures 322. For example, the end E1 of the TGV 310 exposed form the surface 300T may be directly coupled to the corresponding conductive trace 319 of the RDL layer RDL1 of the RDL structure 316. In addition, the end E2 of the TGV 310 exposed form the surface 300B may be coupled to the corresponding conductive ball structure 322 through the conductive pad 321. The end E2 of the TGV 310 exposed form the surface 300B may be coupled to the corresponding conductive ball structure 322 without using any RDL structure.

In some embodiments, the TGV 310 and the conductive pad 321 may be formed a conductive material, such as metals comprising copper, gold, silver, or other applicable metals. In some embodiments, the TGV 310 and the conductive pad 321 may be formed by a plating process, such as chemical plating, electroplating or electro-less plating.

In some embodiments, there is no RDL structure disposed on the surface 300B of the glass carrier 300 and located between the glass carrier 300 and the conductive pad 321.

The first die 332 and the second die 334 are disposed side-by-side on the surface 316TS of the RDL structure 316 as shown in FIG. 1 in the direction D10. The first die 332 has an active surface 332a and a backside surface 332b opposite the active surface 332a. The second die 334 has an active surface 334a and a backside surface 334b opposite the active surface 334a. In some embodiments, the first die 332 and the second die 334 are fabricated using flip-chip technology, and they are flipped to be disposed on the RDL structure 316 opposite the conductive ball structures 322. The active surface 332a and 334a may face the RDL structure 316 on the surface 300T of the glass carrier 300. In other words, the conductive ball structures 322 are disposed on the surface 300B of the glass carrier 300 and opposite the first die 332 and the second die 334. In addition, the RDL structure 316 and the glass carrier 300 are disposed between the first die 332, the second die 334 and the conductive ball structures 322. The conductive ball structures 322 are electrically connected to the first die 332 and the second die 334 by the conductive pads 321, the TGVs 310 and the RDL structure 316.

In some embodiments, the first die 332 and the second die 334 have different functions. For example, the first die 332 includes a logic die, and the second die 334 includes a memory die. The logic die may include a system-on-chip (SoC), a central processing unit (CPU) die, a graphic processing unit (GPU) die, a radio frequency (RF) die, a micro control unit (MCU) die, a microprocessor unit (MPU) die, a power management integrated circuit (PMIC) die, a global positioning system (GPS) device, or an application processor (AP) die, or any combination thereof. The memory die may include a dynamic random access memory (DRAM) die, a high bandwidth memory (HBM) die, the like, or any combination thereof. For example, the second die 334 may be HBM2 or HBM3, but not limited thereto. HBM is a memory chip with low power consumption and ultra-wide communication lanes.

In some embodiments, the first die 332 may be mounted on the RDL structure 316 by conductive bump structures 333. The second die 334 may be mounted on the RDL structure 316 by conductive bump structures 335. The conductive bump structures 333 and 335 are in contact with and coupled to the RDL structure 316.

In some embodiments, the conductive bump structures 333 and 335 may include microbumps. In some embodiments, each of the conductive bump structures 333 and 335 may include an under bump metallurgy (UBM) structure (not shown) and a conductive ball structure (not shown) on the UBM structure. In some embodiments, the conductive bump structures 333 and 335 may include materials such as nickel, copper, gold, palladium, SnAg solder, or a combination thereof.

In some embodiments, there is no specific limitation on the number of dies that can be included in the semiconductor package 500A, and the semiconductor package 500A can contain one, two, or more dies. In this embodiment, two dies are used as an example. For semiconductor packages with multiple dies, the structure described in this embodiment can offer a rigid structure.

As shown in FIG. 1, the semiconductor package 500A further includes an underfill 340 filling the gap between the first die 332 and the RDL structure 316, and the gap between the second die 334 and the RDL structure 316. The underfill 340 may fill the gap between the first die 332 and the second die 334. In some embodiments, the underfill 340 surrounds a portion of the first die 332, a portion of the second die 334, and the conductive bump structures 333 and 335 and is in contact with a portion of the RDL structure 316 to further reduce the thermal resistance from the first die 332 and the second die 334 to the RDL structure 316. In addition, the underfill 340 may be disposed to compensate for differing coefficients of thermal expansion (CTEs) between the first die 332, the second die 334, the conductive bump structures 333, 335 and the RDL structure 316.

As shown in FIG. 1, the molding compound 350 is disposed on the glass carrier 300 and the RDL structure 316. In addition, the molding compound 350 surrounds and is in contact with the first die 332 and the second die 334. The backside surface 332b of the first die 332 and the backside surface 334b of the second die 334 may be covered by or exposed form the molding compound 350. In some embodiments, the molding compound 350 is in contact with the surface 316TS of the RDL structure 316 exposed form the first die 332, the second die 334 and the underfill 340. In some embodiments, side surfaces 350S of the molding compound 350 are flush with the corresponding side surfaces 316S of the RDL structure 316 and the corresponding side surfaces 300S of the glass carrier 300. The side surfaces 316S of the RDL structure 316 and the corresponding side surfaces 300S of the glass carrier 300 may be exposed from the molding compound 350.

In some embodiments, the molding compound 350 may be formed of a nonconductive material, such as an epoxy, a resin, a moldable polymer, or the like. The molding compound 350 may be applied while substantially liquid, and then may be cured through a chemical reaction, such as in an epoxy or resin. In some other embodiments, the molding compound 350 may be an ultraviolet (UV) or thermally cured polymer applied as a gel or malleable solid capable of being disposed around the first die 302 and the second die 304, and then may be cured using a UV or thermally curing process. The molding compound 350 may be cured with a mold (not shown).

As shown in FIG. 1, the semiconductor package 500A further includes at least one discrete electrical component 360 embedded in the glass carrier 300. For example, the electrical component 360 is disposed in a cavity (not shown) of the glass carrier 300. In addition, pads (not shown) of the electrical component 360 may be exposed form the surface 300T or the surface 300B of the glass carrier 300. In addition, the electrical component 360 may be coupled to the RDL structure 316 or the corresponding conductive pad 321.

In some embodiments, the electrical component 360 includes integrated passive device (IPD). For example, the electrical component 360 includes resistor, inductor, capacitor (e.g., a deep trench capacitor (DTC)), or a combination thereof.

A method for forming the semiconductor package packages 500A of FIG. 1 is a chip-first method and described as follows. In some embodiments, the method for forming the semiconductor package 500A may simultaneously form periodically arranged semiconductor package packages 500A.

First, a glass carrier 300 is provided. In some embodiments, the glass carrier 300 may include TGVs 310 passing through the glass carrier 300. In some embodiments, passivation films 306 and 308 may be optionally formed on opposite side surfaces 300S and a surface 300B of the glass carrier 300. In some embodiments, the glass carrier 300 may include at least one discrete electrical component 360 embedded in the glass carrier 300.

Next, multiple deposition and patterning processes are performed to form a RDL structure 316 only on a surface 300T of the glass carrier 300 (or on a single side of the of the glass carrier 300).

Next, a first die 332 and a second die 334, along with conductive bump structures 333 and 335, are side-by-side disposed on the RDL structure 316 by a pick and place process. Next, a solder reflow process is performed so that the first die 302, the second die 304 are coupled to the conductive pads of the RDL structure 316 by the conductive bump structures 333 and 335. Next, an underfill 340 is introduced (dispensed) into gaps between the first die 332, the second die 334 and the RDL structure 316 (or gaps between the first die 332, the second die 334, the third die 432, the fourth die 434 and the RDL structure 316) by an underfilling process.

Next, a molding process is performed to form a molding compound 350 on the RDL structure 316 and surrounding the first die 332 and the second die 334.

Next, a bumping process is performed to form the conductive ball structure 322 on the surface 300B of the glass carrier 300 and opposite the RDL structure 316.

Next, a singulation process is performed to dice the process is performed to cut the molding compound 350, the RDL structure 316 and the glass carrier 300 along scribe lines (not shown) into individual units. After performing the aforementioned processes, a semiconductor package 500A as shown in FIG. 1 is formed.

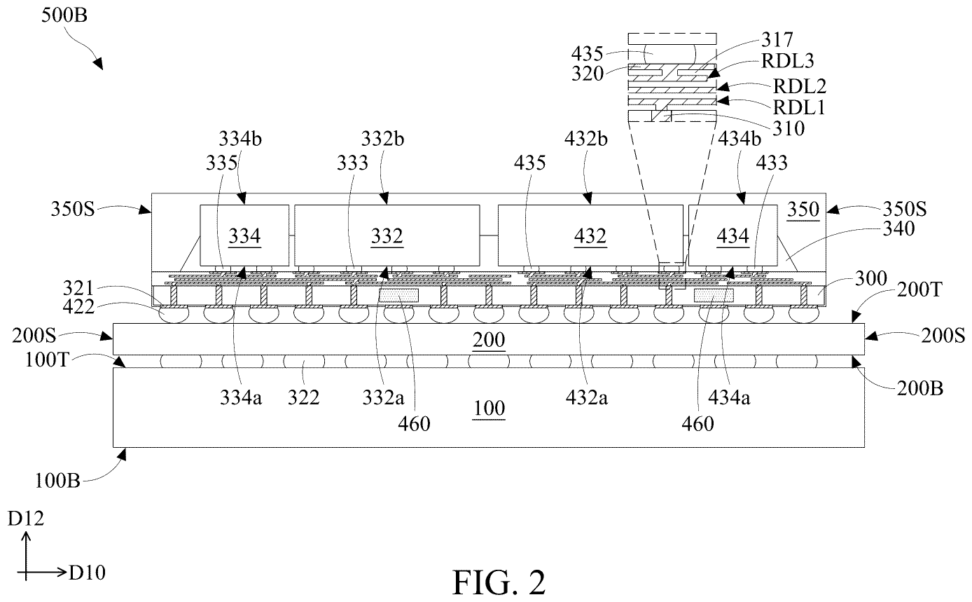

FIG. 2 is a schematic cross-sectional view of a semiconductor package in accordance with some embodiments of the disclosure. Elements of the embodiments hereinafter, that are the same or similar as those previously described with reference to FIG. 1, are not repeated for brevity. As shown in FIGS. 1 and 2, the difference between the semiconductor package 500A and the semiconductor package 500B at least includes that the semiconductor package 500B further includes a substrate 200 located between a glass carrier 300 and a base 100.

In some embodiments, the semiconductor package 500B includes the substrate 200, the glass carrier 300, a redistribution layer (RDL) structure 316, a first die 332, a second die 334, a third die 432, a fourth die 434, a molding compound 350, a plurality of conductive bump structures 422 and a plurality of conductive ball structures 322.

As shown in FIG. 2, the substrate 200 may include a multi-layered package substrate. The substrate 200 may provide mechanical support and electrical connections between dies and conductive ball structures attached to surfaces 200T and 200B of the substrate 200. The substrate 200 may have various types including, for example, cored substrates, including thin core, thick core (e.g., bismaleimide-triazine resin (BT), FR-4 type fibrous board material, glass fiber, or glass), and laminate core. Alternatively, the cored package substrates, for example, can be built up layer by layer around a central core, with layers of conductive material (usually copper) separated by layers of insulating dielectric, with interlayer connections being formed with through holes or vias (microvias).

The substrate 200 may have various types including, for example, a core substrate or a coreless substrate (e.g., the laminate substrate). In some embodiments in which the substrate 200 is a core substrate, the substrate 200 includes a core and RDL structures disposed on the top surface and the bottom surface of the core. In some embodiments, the core may be formed of an organic material, a glass material, a ceramic material, a semiconductor material, the like, or a combination thereof. The organic material may include polypropylene, prepreg (PP), fiberglass resin (e.g., FR-4), bismaleimide triazine (BT) resin, the like, or a combination thereof. The semiconductor material may include silicon, germanium, or a compound material, including silicon germanium, silicon carbide, gallium arsenic, silicon germanium carbide, the like, or a combination thereof. In some embodiments, the RDL structures may include one or more RDL layers alternatively arranged with one or more dielectric build-up layers. In some embodiments, the RDL layers of the substrate 200 may have the same or similar materials and structures. In some embodiments, the dielectric build-up layers may be formed of organic materials, which include a polymer base material, non-organic materials, which include extra-low K (ELK) dielectrics and/or ultra-low K (ULK) dielectric, or the like. For example, the dielectric layers are made of a polymer base material.

In some embodiments in which the substrate 200 is a coreless substrate, the substrate 200A is fabricated without the core, and the RDL structures are laminated each other.

The substrate 200 has opposite surfaces 200T and 200B and opposite side surfaces 200S connected between the surfaces 200T and 200B.

As shown in FIG. 2, the glass carrier 300 is mounted on the surface 200T of the substrate 200 through a bonding process that uses conductive bump structures 422. In some embodiments, the conductive bump structures 422 are disposed on the surface 300B of the glass carrier 300 and coupled between the RDL structure 316 and the substrate 200. In addition, the end E2 of the TGV 310 exposed form the surface 300B may be coupled to the corresponding conductive bump structure 422 through the conductive pad 321.

In some embodiments, the conductive bump structures 422 include controlled collapse chip connection (C4) bumps, another suitable conductive connector, or a combination thereof.

The RDL structure 316 of the semiconductor package 500B is directly disposed on the surface 300T of the glass carrier 300. In some embodiments, the RDL structure 316 of the semiconductor packages 500A and 500B may have the same arrangements, structure, materials, and fabrication processes.

The first die 332, the second die 334, the third die 432, and the fourth die 434 are disposed side-by-side on the surface 316TS of the RDL structure 316 as shown in FIG. 2 in the direction D10. Similar to the first die 332, the third die 432 has an active surface 432a and a backside surface 432b opposite the active surface 432a. Similar to the second die 334, The fourth die 434 has an active surface 434a and a backside surface 434b opposite the active surface 434a. In some embodiments, the first die 332, the second die 334, the third die 432, and the fourth die 434 are fabricated using flip-chip technology, and they are flipped to be disposed on the RDL structure 316 opposite the conductive bump structures 422. The active surfaces 332a, 334a 432a and 434a may face the RDL structure 316 on the surface 300T of the glass carrier 300. In other words, the conductive bump structures 422 are disposed on the surface 300B of the glass carrier 300 and opposite the first die 332, the second die 334, the third die 432 and the fourth die 434. In addition, the RDL structure 316 and the glass carrier 300 are disposed between the first die 332, the second die 334, the third die 432, the fourth die 434 and the conductive bump structures 422. The conductive bump structures 422 are electrically connected to the first die 332, the second die 334, the third die 432 and the fourth die 434 by the conductive pads 321, the TGVs 310 and the RDL structure 316. The conductive ball structures 322 are electrically connected to the first die 332, the second die 334, the third die 432 and the fourth die 434 by the substrate 200, the conductive bump structures 422, the conductive pads 321, the TGVs 310 and the RDL structure 316. In some embodiments, because the present disclosure uses the glass carrier 300 as a support, it can accommodate more dies arranged side by side. The glass carrier 300 supports not only the RDL structure 316 but also multiple dies (e.g., the first die 332, the second die 334, the third die 432, and the fourth die 434) that are placed on the RDL structure 316.

In some embodiments, the third die 432 and the fourth die 434 have different functions. For example, the third die 432 includes a logic die, and the fourth die 434 includes a memory die. In some embodiments, the logic dies (e.g., the first die 332 and the third die 432) may be arranged in the central region of the surface 300T of the glass carrier 300. In addition, the memory dies (e.g., the second die 334 and the fourth die 434) may be arranged in the peripheral region of the surface 300T of the glass carrier 300.

In some embodiments, the third die 432 may be mounted on the RDL structure 316 by conductive bump structures 433. The fourth die 434 may be mounted on the RDL structure 316 by conductive bump structures 435. The conductive bump structures 433 and 435 are in contact with and coupled to the RDL structure 316. In some embodiments, the conductive bump structures 333, 335, 433, and 435 may have the same or similar sizes, materials and structures.

As shown in FIG. 2, the side surfaces 200S of the substrate 200 are not level with the corresponding side surfaces 316S of the RDL structure 316 and the corresponding side surfaces 300S of the glass carrier 300. In some embodiments, the glass carrier 300 glass carrier 300 partially covers the side surfaces 350S of the molding compound 350 in the direction D12. In a plan view, the size (or the area) of the substrate 200 is larger than the size (or the area) of the RDL structure 316 and the size (or the area) of the glass carrier 300.

As shown in FIG. 2, the substrate 200 is mounted on the base 100 through a bonding process that uses the conductive ball structures 322. In some embodiments, the conductive ball structures 322 are disposed on the surface 200B of the substrate 200 opposite the glass carrier 300. In addition, the conductive ball structures 322 are coupled between the substrate 200 and the base 100.

In some embodiments, the conductive ball structures 322 and the second conductive bump structures 422 are disposed on opposite surfaces 200B and 200T of the substrate 200. The size of conductive bump structures 422 may be greater than the size of the conductive bump structures 333 and 335 and smaller than the size of the conductive ball structures 322.

As shown in FIG. 2, the semiconductor package 500B further includes an underfill 340 filling the gaps between the first die 332, the second die 334, the third die 432, the fourth die 434 and the RDL structure 316. The underfill 340 also fills the gaps between the first die 332, the second die 334, the third die 432, and the fourth die 434.

The molding compound 350 the molding compound 350 is disposed on the glass carrier 300 and the RDL structure 316. In addition, the molding compound 350 surrounds and is in contact with the first die 332, the second die 334, the third die 432, and the fourth die 434.

As shown in FIG. 2, the semiconductor package 500B further includes one or more discrete electrical components 460 embedded in the glass carrier 300. For example, the electrical components 460 is disposed in discrete cavities (not shown) of the glass carrier 300. In addition, pads (not shown) of the electrical components 460 may be exposed form the surface 300T or the surface 300B of the glass carrier 300. In addition, the electrical components 460 may be coupled to the RDL structure 316 or the corresponding conductive pad 321. In some embodiments, the electrical components 460 may include the same or different types of integrated passive device (IPD) including resistor, inductor, capacitor (e.g., a deep trench capacitor (DTC)), or a combination thereof.

A method for forming the semiconductor package packages 500B of FIG. 2 is a chip-first method and described as follows. In some embodiments, the method for forming the semiconductor package 500B may simultaneously form periodically arranged semiconductor package packages 500B.

First, a glass carrier 300 is provided. In some embodiments, the glass carrier 300 may include TGVs 310 passing through the glass carrier 300. In some embodiments, passivation films 306 and 308 may be optionally formed on opposite side surfaces 300S and a surface 300B of the glass carrier 300. In some embodiments, the glass carrier 300 may include at least one discrete electrical component 360 embedded in the glass carrier 300.

Next, multiple deposition and patterning processes are performed to form a RDL structure 316 only on a surface 300T of the glass carrier 300.

Next, a first die 332, a second die 334, a third die 432 and a fourth die 434, along with conductive bump structures 333, 335, 433 and 435, are side-by-side disposed on the RDL structure 316 by a pick and place process. Next, a solder reflow process is performed so that the first die 302, the second die 304, the third die 432, the fourth die 434 are coupled to the conductive pads of the RDL structure 316 by the conductive bump structures 333, 335, 433 and 435. Next, an underfill 340 is introduced (dispensed) into gaps between the first die 332, the second die 334, the third die 432, the fourth die 434 and the RDL structure 316 by an underfilling process.

Next, a molding process is performed to form a molding compound 350 on the RDL structure 316 and surrounding the first die 332, the second die 334, the third die 432 and the fourth die 434.

Next, a bumping process is performed to form conductive bump structure 422 on the surface 300B of the glass carrier 300 and opposite the RDL structure 316.

In some embodiments, the intermediate steps of the method for forming the semiconductor package 500B may simultaneously form periodically arranged units including the glass carrier 300, the RDL structure 316, the first die 302, the second die 304, the third die 432, the fourth die 434, the conductive bump structures 333, 335, 433 and 435, the underfill 340, the molding compound 350 and the conductive bump structure 422.

Next, a singulation process is performed to dice the process is performed to cut the molding compound 350, the RDL structure 316 and the glass carrier 300 along scribe lines (not shown) into individual units.

Next, a bonding process is performed to mount the individual unit on a surface 200T of a substrate 200.

Next, a bumping process is performed to form conductive ball structure 322 on the surface 200B of the substrate 200 and opposite the glass carrier 300.

After performing the aforementioned processes, a semiconductor package 500B as shown in FIG. 2 is formed.

The semiconductor packages 500A and 500B have the following advantages. The semiconductor packages 500A and 500B include an organic RDL structure (e.g., the RDL structure 316) along with a rigid carrier (e.g., the glass carrier 300) for enhancement of structural strength. The semiconductor packages 500A and 500B including the glass carrier could offer a larger fan-out package size with a high density routing that can be mounted on a base (e.g., a PCB) while fulfill requirements of the board level reliability (BLR) and surface-mount technology (SMT) warpage control. The redistribution layer (RDL) trace broken risk is eliminated. The stress, coplanarity and reliability performance can be improved. In addition, because the glass carrier is rigid and has a low coefficient of thermal expansion (CTE), the semiconductor packages 500A and 500B may provide better performance of low warpage and dimensional stability at high temperatures for bump joint. Further, the glass carrier of the semiconductor packages 500A and 500B enable the possibility of adding additional IPDs (e.g., the capacitor) to improve IR drop performance. Since the glass carrier is originally used in the chip-last process for the semiconductor packages 500A and 500B, no additional substrate supporting the organic RDL structure is required, the fabrication cost can be reduced.

Embodiments provide a semiconductor package. The semiconductor package includes a glass carrier, a redistribution layer (RDL) structure, a first die, a molding compound and a plurality of conductive ball structures. The RDL structure is directly disposed on a first surface of the glass carrier. The first die is mounted on the RDL structure. The molding compound is disposed on the RDL structure and surrounding the first die. The plurality of conductive ball structures is disposed on a second surface of the glass carrier. The second surface is opposite the first surface.

In some embodiments, a side surface of the glass carrier is flush with a corresponding side surface of the RDL structure.

In some embodiments, a side surface of the glass carrier is positioned lower than the corresponding side surface of the RDL structure in the horizontal direction.

In some embodiments, the semiconductor package further includes a second die mounted on the RDL structure and disposed side by side with the first die.

In some embodiments, the first die is a logic die, and the second die is a memory die.

In some embodiments, the semiconductor package further includes at least one through glass via passing through the glass carrier and connected between the RDL structure and one of the plurality of conductive ball structures.

In some embodiments, the semiconductor package further includes a substrate and a plurality of conductive bump structures. The substrate is disposed between the glass carrier and the conductive ball structures. The plurality of conductive bump structures is disposed between the glass carrier and the substrate.

In some embodiments, the semiconductor package further includes at least one discrete electrical component embedded in the glass carrier.

In some embodiments, the semiconductor package further includes a first passivation film covering a side surface of the glass carrier.

In some embodiments, the semiconductor package further includes a second passivation film covering the first surface of the glass carrier.

Embodiments provide a semiconductor package. The semiconductor package includes a glass carrier, an organic redistribution layer (RDL) structure, a first die, a molding compound and a plurality of conductive ball structures. The organic RDL structure is directly disposed on a first surface of the glass carrier. The first die is mounted on the organic RDL structure and opposite the glass carrier. The molding compound is disposed on the organic RDL structure and surrounding the first die. The plurality of conductive ball structures is disposed on a second surface of the glass carrier. The second surface is opposite the first surface.

In some embodiments, the first die is mounted on the organic RDL by first conductive bump structures.

In some embodiments, a side surface of the glass carrier is flush with a side surface of the organic RDL structure.

In some embodiments, the semiconductor package as claimed in claim 11, further includes a second die mounted on the organic RDL structure and disposed side by side with the first die. The first and second dies have different functions.

In some embodiments, the semiconductor package further includes a third die and a fourth die mounted on the organic RDL structure and disposed side by side with the first die and the second die. The first and second dies have different functions.

In some embodiments, the semiconductor package further includes a substrate disposed between the glass carrier and the conductive ball structures. The glass carrier is mounted on the substrate by second conductive bump structures.

In some embodiments, the semiconductor package further includes at least one through glass via passing through the glass carrier and connected between the organic RDL structure and the substrate.

In some embodiments, the semiconductor package further includes at least one discrete electrical component embedded in the glass carrier.

In some embodiments, the conductive ball structures and the second conductive bump structures are disposed on opposite surfaces of the substrate.

In some embodiments, the semiconductor package, further includes a passivation film covering a surface of the glass carrier not covered by the organic RDL structure.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor package, comprising:
a glass carrier;
a redistribution layer (RDL) structure directly disposed on a first surface of the glass carrier;
a first die mounted on the RDL structure;
a molding compound disposed on the RDL structure and surrounding the first die; and
a plurality of conductive ball structures disposed on a second surface of the glass carrier, wherein the second surface is opposite the first surface.

2. The semiconductor package as claimed in claim 1, wherein a side surface of the glass carrier is flush with a corresponding side surface of the RDL structure.

3. The semiconductor package as claimed in claim 1, wherein a side surface of the glass carrier is positioned lower than the corresponding side surface of the RDL structure in the horizontal direction.

4. The semiconductor package as claimed in claim 1, further comprising:
a second die mounted on the RDL structure and disposed side by side with the first die.

5. The semiconductor package as claimed in claim 4, wherein the first die is a logic die, and the second die is a memory die.

6. The semiconductor package as claimed in claim 1, further comprising:
at least one through glass via passing through the glass carrier and connected between the RDL structure and one of the plurality of conductive ball structures.

7. The semiconductor package as claimed in claim 1, further comprising:
a substrate disposed between the glass carrier and the plurality of conductive ball structures; and
a plurality of conductive bump structures disposed between the glass carrier and the substrate.

8. The semiconductor package as claimed in claim 1, further comprising:
at least one discrete electrical component embedded in the glass carrier.

9. The semiconductor package as claimed in claim 1, further comprising:
a first passivation film covering a side surface of the glass carrier.

10. The semiconductor package as claimed in claim 1, further comprising:
a second passivation film covering the first surface of the glass carrier.

11. A semiconductor package, comprising:
a glass carrier;
an organic redistribution layer (RDL) structure directly disposed on a first surface of the glass carrier;
a first die mounted on the organic RDL structure and opposite the glass carrier;
a molding compound disposed on the organic RDL structure and surrounding the first die; and
a plurality of conductive ball structures disposed on a second surface of the glass carrier, wherein the second surface is opposite the first surface.

12. The semiconductor package as claimed in claim 11, wherein the first die is mounted on the organic RDL by first conductive bump structures.

13. The semiconductor package as claimed in claim 11, wherein a side surface of the glass carrier is flush with a side surface of the organic RDL structure.

14. The semiconductor package as claimed in claim 11, further comprising:
a second die mounted on the organic RDL structure and disposed side by side with the first die, wherein the first and second dies have different functions.

15. The semiconductor package as claimed in claim 14, further comprising:
a third die and a fourth die mounted on the organic RDL structure and disposed side by side with the first die and the second die, wherein the first and second dies have different functions.

16. The semiconductor package as claimed in claim 11, further comprising:
a substrate disposed between the glass carrier and the plurality of conductive ball structures, wherein the glass carrier is mounted on the substrate by second conductive bump structures.

17. The semiconductor package as claimed in claim 16, further comprising:
at least one through glass via passing through the glass carrier and connected between the organic RDL structure and the substrate.

18. The semiconductor package as claimed in claim 16, wherein the conductive ball structures and the second conductive bump structures are disposed on opposite surfaces of the substrate.

19. The semiconductor package as claimed in claim 11, further comprising:
at least one discrete electrical component embedded in the glass carrier.

20. The semiconductor package as claimed in claim 11, further comprising:
a passivation film covering a surface of the glass carrier not covered by the organic RDL structure.
